(19) United States
(12) Patent Application Publication
(10) Pub. No.: US 2010/0203448 A1
(43) Pub. Date: Aug. 12, 2010

(54) METHOD FOR MANUFACTURING PRINTING PLATE AND PRINTING PLATE-FORMING PHOTOCURABLE LIQUID FOR MANUFACTURING

(75) Inventors: Takashi TESHIMA, Shiojiri-shi (JP); Yoshiro KOGA, Shiojiri-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/700,037

(22) Filed: Feb. 4, 2010

(30) Foreign Application Priority Data
Feb. 9, 2009 (JP) 2009-027814

(51) Int. Cl. G03F 7/20; G03C 1/00

(52) U.S. Cl. 430/280.1; 430/300

(57) ABSTRACT

A method for manufacturing a printing plate includes applying a printing plate-forming photocurable liquid containing an epoxy-modified fatty acid ester and/or an acrylic-modified fatty acid ester and a photopolymerization initiator onto a printing original plate to form an uncured coating, selectively irradiating the uncured coating with UV light to cure part of the coating, and removing the uncured portion of the coating.

### CROSS-REFERENCE TO RELATED APPLICATION

The entire disclosure of Japanese Patent Application No. 2009-027814, filed Feb. 9, 2008 is expressly incorporated by reference herein.

### BACKGROUND

1. Technical Field

The present invention relates to a method for manufacturing a printing plate and a photocurable liquid for forming a printing plate.

2. Related Art

For manufacturing a printing plate, in general, a photoresist layer having a predetermined pattern is formed on a substrate of a aluminum plate, a zinc plate or the like, and recesses or grooves are formed in the substrate by, for example, wet etching (chemical etching) or plasma etching using the photoresist layer as a mask, as disclosed in, for example, JP-A-5-273742.

There are however concerns that such a known process may have an environmental impact because an organic solvent or the like is used to remove the photoresist layer, and, after etching, an etchant must be disposed of. In addition, the known process requires many steps for manufacturing the printing plate and is accordingly complicated.

### SUMMARY

An advantage of some aspects of the invention is that it provides an environmentally friendly method for easily manufacturing a durable printing plate, and a printing plate-forming photocurable liquid.

According to an aspect of the invention, a method for manufacturing a printing plate is provided. In the method, a printing plate-forming photocurable liquid containing an epoxy-modified fatty acid ester and/or an acrylic-modified fatty acid ester and a photopolymerization initiator is applied onto a printing original plate to form an uncured coating. The uncured coating is selectively irradiated with UV light to be partially cured. The uncured portion of the coating is removed.

Preferably, the UV light has an irradiation energy of 25 to 500 mJ/cm².

According to another aspect of the invention, a printing plate-forming photocurable liquid is provided which contains an epoxy-modified fatty acid ester and/or an acrylic-modified fatty acid ester, and a photopolymerization initiator.

When the printing plate-forming photocurable liquid contains the epoxy-modified fatty acid ester, the photopolymerization initiator is preferably a cationic photopolymerization initiator.

When the printing plate-forming photocurable liquid contains the acrylic-modified fatty acid ester, the photopolymerization initiator is preferably a radical photopolymerization initiator.

Preferably, the epoxy-modified fatty acid ester is an epoxidized vegetable oil prepared by epoxy-modifying a vegetable oil.

Preferably, the acrylic-modified fatty acid ester is an epoxidized vegetable oil acrylate prepared by acrylic-modifying an epoxidized vegetable oil prepared by epoxy-modifying a vegetable oil.

Preferably, the cationic photopolymerization initiator is an aromatic sulfonium salt or an aromatic iodonium salt.

Preferably, the cationic photopolymerization initiator is contained in a proportion of 0.5 to 8 parts by weight relative to 100 parts by weight of the epoxy-modified fatty acid ester.

Preferably, the radical photopolymerization initiator is an α-hydroxy ketone compound or an oxime ester compound.

Preferably, the radical photopolymerization initiator is contained in a proportion of 0.5 to 8 parts by weight relative to 100 parts by weight of the acrylic-modified fatty acid ester.

The method according to embodiments of the invention can easily and simply manufacture a durable printing plate, and the method and the printing plate-forming photocurable liquid are environmentally friendly.

### BRIEF DESCRIPTION OF THE DRAWINGS

The invention will be described with reference to the accompanying drawings, wherein like numbers reference like elements.

FIG. 1 is a schematic representation of a printing plate manufacturing apparatus used in a method for manufacturing a printing plate according to an embodiment of the invention.

FIG. 2 is a schematic sectional view of a UV irradiation unit provided in the printing plate manufacturing apparatus shown in FIG. 1.

### DESCRIPTION OF EXEMPLARY EMBODIMENTS

Preferred embodiments of the invention will now be described in detail.

### Printing Plate-Forming Photocurable Liquid

Before describing the method for manufacturing a printing plate, a printing plate-forming photocurable liquid will be describe. The printing plate-forming photocurable liquid contains an epoxy-modified fatty acid ester and/or an acrylic-modified fatty acid ester, and a photopolymerization initiator.

The known method requires many steps to manufacture printing plates and is accordingly complicated. In addition, there are concerns that the known method may have an environmental impact because an organic solvent and an etchant or the like are used.

In the method according to embodiments of the invention, on the other hand, the printing plate is manufactured by forming a recessed pattern on the printing original plate using a photocurable liquid containing an epoxy-modified fatty acid ester and/or an acrylic-modified fatty acid ester and a photopolymerization initiator. This method is simple and environmentally friendly.

Constituents of the photocurable liquid will now be described in detail.

### Epoxy-Modified Fatty Acid Ester

The epoxy-modified fatty acid ester will first be described below. The epoxy-modified fatty acid ester has a three-membered ring called epoxy group (oxirane ring) in its molecular structure.

The epoxy-modified fatty acid ester is a liquid that can be rapidly cured by being irradiated with an energy ray such as UV light or electron beam, with combined use of a below-described photopolymerization initiator (particularly, a cationic photopolymerization initiator). In particular, when a liquid containing an epoxy-modified fatty acid ester and a cationic photopolymerization initiator is irradiated with an energy ray, such as UV light or electron beam, the cationic photopolymerization initiator is activated to produce a hydrogen ion. The hydrogen ion reacts with the epoxy group of the epoxy-modified fatty acid ester to promote a curing reaction and polymerization reaction of the epoxy-modified compound, so that the liquid is cured. A recessed pattern can be formed on the printing original plate by the curing reaction of the epoxy-modified fatty acid ester, as will be described below. The resulting cured film has a dense three-dimensional network structure, and accordingly has such a durability as is resistant to, for example, heat and solvents, and also has high hardness.

Since the epoxy-modified fatty acid ester is a type of fatty acid ester, which has characteristics similar to oils and fats, it can be easily removed before being cured by absorbing it with a sponge-like member or washing it away with water, a cleaning solution containing a surfactant or the like. Therefore, it can be removed without using an organic solvent, an etchant or the like, and is thus environmentally friendly. Thus, the use of an epoxy-modified fatty acid ester can provide an environmentally friendly method.

The epoxy-modified fatty acid ester can be cured in a very short time. Accordingly, the use of the epoxy-modified fatty acid ester can increase the productivity in manufacture of printing plates.

The epoxy-modified fatty acid ester may be an epoxide produced by modifying into an epoxy group at least part of carbon-carbon double bonds (C═C) of, for example, a vegetable oil or a mineral oil.

In particular, vegetable oils have a large number of carbon-carbon double bonds in their molecular structures. Accordingly, epoxidized vegetable oils prepared from the vegetable oils have a large number of epoxy groups, and can react with a hydrogen ion to induce favorably a curing reaction and a polymerization reaction. Hence, by using an epoxidized vegetable oil as the epoxy-modified fatty acid ester, a cured film having a denser three-dimensional network structure can be formed, and a durable printing plate can be manufactured.

In general, vegetable oils mainly contain a fatty acid triglyceride that is a triester (triglyceride) of a fatty acid and glycerin, and includes an unsaturated fatty acid (fatty acid having a carbon-carbon double bond in its main chain) as a fatty acid component.

Preferably, the vegetable oil to be epoxidized for use as an epoxidized vegetable oil contains an unsaturated fatty acid having at least two carbon-carbon double bonds as an component. The epoxidized vegetable oil prepared by epoxy-modifying such a vegetable oil can be cured in a shorter time, and the hardness after curing is sufficiently high.

Vegetable oils that can be epoxy-modified to prepare the epoxidized vegetable oil include drying oils, such as dehydrated castor oil, tung oil, linseed oil, sunflower oil, rose hip oil, and perilla oil; and semidrying oils, such as soybean oil, rapeseed oil, safflower oil, cotton seed oil, sesame oil, and corn oil.

Among those vegetable oils preferred are linseed oil and soybean oil. Hence, epoxidized linseed oil prepared by epoxy-modifying linseed oil and epoxidized soybean oil prepared by epoxy-modifying soybean oil are suitable to be used as the epoxidized vegetable oil. Linseed oil and soybean oil, which may be used as the starting material, are stable and contain a relatively large number of carbon-carbon double bonds in their molecular structure. Therefore, epoxidized linseed oil and epoxidized soybean oil prepared from these vegetable oils can react with the hydrogen ion derived from the below-described cationic photopolymerization initiator, thus being cured and polymerized favorably. Consequently, the productivity of the printing plate can be enhanced, and the resulting cured film can tightly adhere to the printing original plate.

Preferably, the vegetable oil has an iodine number of 70 to 220, more preferably 80 to 200. Since such vegetable oils include a large number of carbon-carbon double bonds in their molecular structure, the epoxidized vegetable oils produced by epoxy-modifying these vegetable oils can contain a large number of epoxy groups (oxirane rings) in their molecular structure. A disperse medium mainly containing such an epoxidized vegetable oil can be cured in a shorter time by UV irradiation, and the hardness after curing can be sufficiently high. Consequently, the productivity of the printing plate can be enhanced, and the resulting printing plate can be particularly durable.

Preferably, the epoxidized vegetable oil has an iodine number of 15 or less, more preferably 10 or less. Such an epoxidized vegetable oil can be cured in a shorter time by UV irradiation, and the hardness after curing can be sufficiently high. Consequently, the productivity of the printing plate can be enhanced, and the resulting printing plate can be particularly durable.

Preferably, the iodine numbers of the epoxidized vegetable oil and the vegetable oil before epoxy modification satisfy the relationship 0≦I₁/I₂≦0.17, more preferably 0.01≦I₁/I₂≦0.11, wherein I₁ represents the iodine number of an epoxidized vegetable oil and I₂ represents the iodine number of the vegetable oil before epoxy modification. Epoxidized vegetable oils satisfying the above relationship contain epoxy groups in a high proportion in their molecular structure and can accordingly be cured in a shorter time by UV irradiation, and the hardness after curing can be sufficiently high. Consequently, the productivity of the printing plate can be enhanced, and the resulting printing plate can be particularly durable. The cured film formed by curing such an epoxidized vegetable oil can be highly solvent-resistant.

### Acrylic-Modified Fatty Acid Ester

An acrylic-modified fatty acid ester has a (meth)acryloyl group in its molecular structure. As with the epoxy-modified fatty acid ester, the acrylic-modified fatty acid ester is a liquid that can be rapidly cured by being irradiated with an energy ray, such as UV light or electron beam, with combined use of a photopolymerization initiator (particularly a radical photopolymerization initiator). In particular, when a liquid containing an acrylic-modified fatty acid ester and a radical photopolymerization initiator is irradiated with an energy ray, such as UV light or electron beam, the radical photopolymerization initiator is activated to produce a radical. The radical activates the (meth)acryloyl group (more specifically, vinyl group of the (meth)acryloyl group) of the acrylic-modified fatty acid ester to promote a curing reaction and polymerization reaction of the acrylic-modified fatty acid ester, so that the liquid is cured. A recessed pattern can be formed on the printing original plate by the curing reaction of the acrylic-modified fatty acid ester, as will be described below. The resulting cured film has a dense three-dimensional network structure, and accordingly has such a durability as is resistant to, for example, heat and solvents, and also has high hardness.

Since the acrylic-modified fatty acid ester is a type of fatty acid ester, which has characteristics similar to oils and fats, it can be easily removed before being cured by absorbing it with a sponge-like member or washing it away with water, a cleaning solution containing a surfactant or the like. Therefore, it can be removed without using an organic solvent, an etchant or the like, and is thus environmentally friendly. Thus, the use of an acrylic-modified fatty acid ester can provide an environmentally friendly method can be provided.

The acrylic-modified fatty acid ester can be cured in a very short time. Accordingly, the use of the acrylic-modified fatty acid ester can increase the productivity in manufacture of printing plates.

The acrylic-modified fatty acid ester may be a (meth)acrylate produced by modifying the epoxy group of the above-described epoxy-modified fatty acid ester (for example, an epoxidized vegetable oil or an epoxidized mineral oil) into a (meth)acryloyl group.

In particular, epoxidized vegetable oil acrylates have a large number of acryloyl groups in their molecular structure because they are prepared from epoxidized vegetable oils having a large number of epoxy groups, and accordingly can react with a radical to induce favorably a curing reaction and a polymerization. Hence, by using an epoxidized vegetable oil acrylate as the acrylic-modified fatty acid ester, a cured film having a denser three-dimensional network structure can be formed, a durable printing plate can be manufactured.

In general, vegetable oils used as the starting material of the epoxidized vegetable oil acrylate mainly contain a fatty acid triglyceride that is a triester of a fatty acid and glycerin, and contains an unsaturated fatty acid (fatty acid having a carbon-carbon double bond in its main chain) as a fatty acid component. The epoxidized vegetable oil can be prepared by modifying at least part of the carbon-carbon double bonds (C═C) of such a vegetable oil into an epoxy group.

Vegetable oils that can be used as the starting material of the epoxy-modified vegetable oil include drying oils, such as dehydrated castor oil, tung oil, linseed oil, sunflower oil, rose hip oil, and perilla oil; and semidrying oils, such as soybean oil, rapeseed oil, safflower oil, cotton seed oil, sesame oil, and corn oil.

Among those vegetable oils preferred is soybean oil. Hence, epoxidized soybean oil acrylate prepared by acrylic-modifying epoxidized soybean oil (epoxide prepared by epoxy-modifying soybean oil) is suitable to be used as the epoxidized vegetable oil acrylate. Soybean oil, which may be used as the starting material, is stable and contains a relatively large number of carbon-carbon double bonds in its molecular structure. Therefore, epoxidized soybean oil acrylate prepared from soybean oil can react with the radical derived from the below-described radical photopolymerization initiator, thus being cured and polymerized favorably. Consequently, the resulting cured film has a denser three-dimensional network structure, thus producing a durable printing plate.

Preferably, the epoxidized vegetable oil acrylate has an iodine number of 15 or less, more preferably 10 or less. Such an epoxidized vegetable oil acrylate contains acryloyl groups in a high proportion in its molecular structure and can accordingly be cured in a shorter time by UV irradiation, and the hardness after curing can be sufficiently high. Thus, the printing plate can be manufactured at a high speed, and the resulting printing plate can be particularly superior in durability.

### Photopolymerization Initiator

Examples of the photopolymerization initiators include cationic photopolymerization initiators and radical photopolymerization initiators.

### Cationic Photopolymerization Initiator

The cationic photopolymerization initiator will first be described below. The cationic photopolymerization initiator is a compound that is activated to produce a hydrogen ion by being irradiated with an energy ray, such as UV light, and mainly functions to induce the curing reaction and polymerization reaction of the epoxy-modified fatty acid ester.

By adding a cationic photopolymerization initiator in a printing plate-forming photocurable liquid, the photocurable liquid applied onto a printing original plate can be rapidly cured to form a film by being irradiated with an energy ray, such as UV light, and the cured film can tightly adhere to the printing original plate. Thus, a durable printing plate can be easily produced.

Examples of such a cationic photopolymerization initiator include diazonium salts containing a counter anion such as a halogen ion, a sulfonic anion, a carboxylic anion, and a sulfuric anion, and onium salts, such as sulfonium salts, iodonium salt, and phosphonium salts.

Among those preferred are aromatic sulfonium salts and aromatic iodonium salts containing an aromatic ring in their molecular structure. Such cationic photopolymerization initiators are chemically stable and are not likely to produce a hydrogen ion by irradiation with any types of energy (for example, thermal energy) except energy rays. Accordingly, these cationic polymerization initiators are not activated, and consequently the epoxy-modified fatty acid ester is not cured or polymerized during storage of the photocurable liquid. The use of the above-described cationic photopolymerization initiator allows the photocurable liquid to be stably stored for the long term, and, in manufacture of the printing plate, the photocurable liquid containing the cationic photopolymerization initiator can be rapidly cured by, for example, UV irradiation.

In addition, those cationic photopolymerization initiators are highly soluble in the epoxy-modified fatty acid ester, and are accordingly difficult to precipitate out of the photocurable liquid. Hence, the precipitation of the cationic photopolymerization initiator can be prevented during storage of the photocurable liquid. Furthermore, those cationic photopolymerization initiators can be uniformly dispersed in the printing plate-forming photocurable liquid. Accordingly, not only the printing plate-forming photocurable liquid applied onto the printing original plate can be rapidly cured by UV irradiation, but also the resulting cured film can adhere uniformly to the printing original plate.

The cationic photopolymerization initiator is contained in the printing plate-forming photocurable liquid preferably in a proportion of 0.1 to 6 parts by weight, more preferably 0.5 to 5 parts by weight, relative to 100 parts by weight of epoxy-modified fatty acid ester. The cationic photopolymerization initiator added in the above range can be uniformly dissolved in the printing plate-forming photocurable liquid to enhance the storage stability of the photocurable liquid. In addition, not only the printing plate-forming photocurable liquid applied onto the printing original plate can be rapidly cured by UV irradiation, but also the resulting cured film can tightly adhere to the printing original plate.

### Radical Photopolymerization Initiator

The radical photopolymerization initiator will now be described. The radical photopolymerization initiator is a compound that is activated to produce a radical by being irradiated with an energy ray, such as UV light, and mainly functions to induce a curing reaction and polymerization reaction of the acrylic-modified fatty acid ester.

By adding a radical photopolymerization initiator in a printing plate-forming photocurable liquid, the photocurable liquid applied onto a printing original plate can be rapidly cured to form a film by being irradiated with an energy ray, such as UV light, and the cured film can tightly adhere to the printing original plate. Thus, a durable printing plate can be easily produced.

Known radical photopolymerization initiators may be used in the printing plate-forming photocurable liquid without particular limitation. Among those preferred are α-hydroxy ketone compounds and oxime ester compounds.

Such radical photopolymerization initiators are solid at room temperature and chemically stable, and are not likely to produce a radical by irradiation with any types of energy (for example, thermal energy) except energy rays. Accordingly, these radical polymerization initiators are not activated, and consequently the acrylic-modified fatty acid ester is not cured or polymerized during storage of the photocurable liquid. The use of the above-describe radical photopolymerization initiators allows the printing plate-forming photocurable liquid to be stably stored for the long term, and, in manufacture of the printing plate, the photocurable liquid containing the radical photopolymerization initiator can be rapidly cured by, for example, UV irradiation.

In addition, those radical photopolymerization initiators are highly soluble in the acrylic-modified fatty acid ester. Hence, the radical photopolymerization initiator can be prevented from precipitating out of the printing plate-forming photocurable liquid during storage of the photocurable liquid. Furthermore, those radical photopolymerization initiators can be uniformly dispersed in the printing plate-forming photocurable liquid. Accordingly, not only the printing plate-forming photocurable liquid applied onto the printing original plate can be rapidly cured by UV irradiation, but also the resulting cured film can adhere uniformly to the printing original plate.

The radical photopolymerization initiator is contained in the printing plate-forming photocurable liquid preferably in a proportion of 0.5 to 8 parts by weight, more preferably 2 to 5 parts by weight, relative to 100 parts by weight of acrylic-modified fatty acid ester. The radical photopolymerization initiator added in the above range can be uniformly dissolved in the printing plate-forming photocurable liquid to enhance the storage stability of the photocurable liquid. In addition, not only the printing plate-forming photocurable liquid applied onto the printing original plate can be rapidly cured by UV irradiation, but also the resulting cured film can tightly adhere to the printing original plate.

### Method for Manufacturing Printing Plate

The method for manufacturing the printing plate according to an embodiment of the invention will now be described.

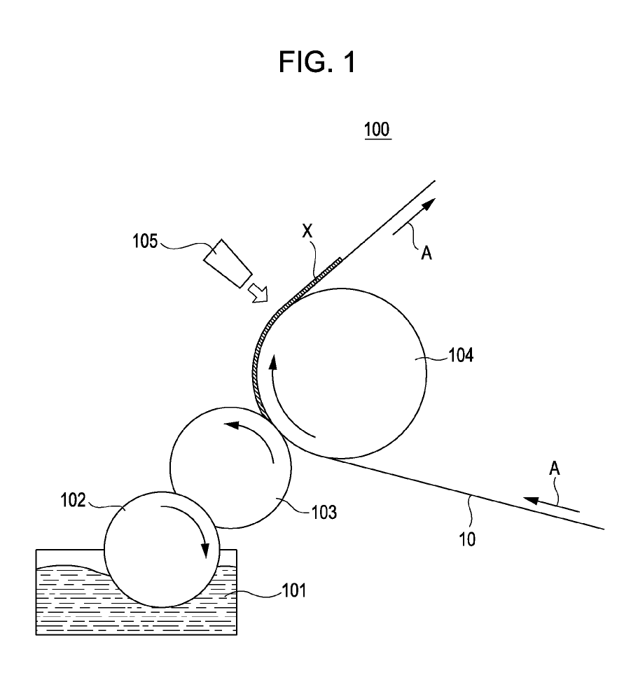

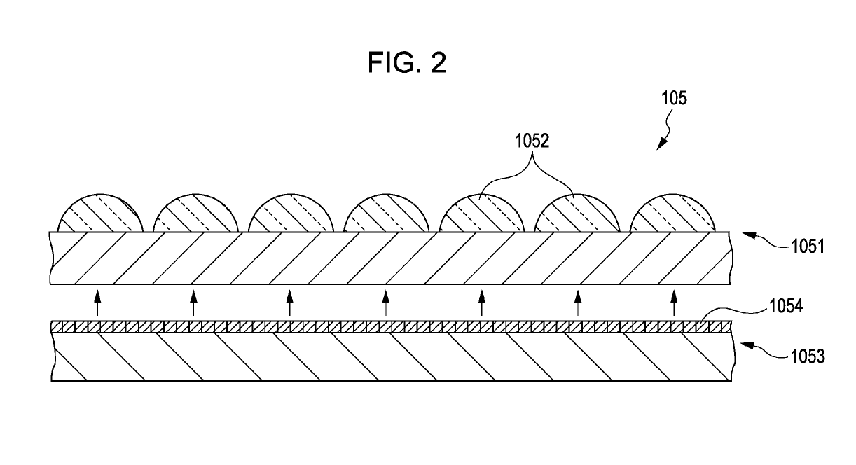

A printing plate manufacturing apparatus will first be described which is used in the printing plate manufacturing method according to an embodiment of the invention. FIG. 1 is a schematic representation of a printing plate manufacturing apparatus used in the method for manufacturing the printing plate according to an embodiment of the invention. FIG. 2 is a schematic sectional view of a UV irradiation unit provided in the printing plate manufacturing apparatus shown in FIG. 1.

As shown in FIG. 1, the printing plate manufacturing apparatus 100 includes a transport member 104 that transports a printing original plate 10, a reservoir 101 in which the printing plate-forming photocurable liquid is stored, a pickup roller 102, an applicator roller 103, and a UV irradiation unit 105.

The transport member 104 is a roller that rotates clockwise in FIG. 1 so as to transport the printing original plate 10 in the direction designated by arrow A.

The reservoir 101 can contain the printing plate-forming photocurable liquid.

The pickup roller 102 feeds the printing plate forming-photocurable liquid to the applicator roller 103 from the reservoir 101.

The applicator roller 103 applies the photocurable liquid fed by the pickup roller 102 onto the printing original plate 10.

The UV irradiation unit 105 selectively irradiates a photocurable liquid coating X formed on the printing original plate with UV light, thus forming an uncured portion and a cured portion in the coating X.

In the present embodiment, the UV irradiation unit (line head) 105 includes a microlens array 1051 and a UV LED substrate 1053 emitting UV light, as shown in FIG. 2.

The microlens array 1051 includes a plurality of microlenses 1052, as shown in FIG. 2. The microlenses 1052 condense UV light emitted from the LED substrate 1053 on the coating X on the printing original plate 10.

In addition, a plurality of light-emitting elements (LEDs) 1054 emitting UV light are disposed on the LED substrate 1053. The light-emitting elements 1054 emit UV light to the microlens array 1051.

Each light-emitting element 1054 is connected to a controller (not shown) that controls the on/off state of the light-emitting element.

Although the UV irradiation unit includes a line head having a microlens array in the present embodiment, the light-emitting unit may be a type that emits UV light through a mask having a predetermined optically transparent portion without being limited to the line head.

An embodiment of the printing plate manufacturing method will be described below.

[1] First, a printing original plate 10 is prepared (printing original plate preparation step). Examples of the printing original plate 10 include plastic sheets, solvent-impermeable paper, and metal sheets, such as of aluminum, zinc, bimetals (copper-aluminum, copper-stainless steel, chromium-copper, etc), and trimetals (chromium-copper-aluminum, chromium-lead-iron, chromium-copper-stainless steel).

[2] Subsequently, the printing original plate 10 is set to the transport member 104 of the printing plate manufacturing apparatus 100 shown in FIG. 1 and is transported. The printing original plate 10 is transported preferably at a speed of 50 to 1000 mm/s, more preferably 200 to 700 mm/s.

[3] Then, while the printing original plate 10 is being transported, the applicator roller 103 applies a printing plate-forming photocurable liquid onto the surface of the printing original plate 10 to form an uncured coating X (photocurable liquid application step).

[4] The uncured coating X on the printing original plate 10 is selectively irradiated with UV light from the UV irradiation unit 105 to cure part of the coating X (UV irradiation step). The coating X thus has an uncured portion and a cured portion.

The irradiation energy of the UV light emitted from the UV irradiation unit 105 is preferably 25 to 500 mJ/cm², more preferably 40 to 500 mJ/cm². Such UV light can efficiently induce a curing reaction and polymerization reaction of the printing plate-forming photocurable liquid.

[5] Then, the uncured portion of the coating X is removed (uncured portion removing step). Any method can be applied to remove the uncured portion. For example, the uncured portion may be absorbed by a sponge-like member or may be washed away with a cleaning solution containing a surfactant. The surfactant can be selected from the known anionic surfactants, cationic surfactants and nonionic surfactants. By removing the uncured portion, a recessed pattern can be formed in the printing original plate 10, and thus a printing plate is produced.

The above-describe method not only can easily manufacture a durable printing plate, but also can reduce environmental load of the process steps.

The resulting printing plate can be applied to any of lithographic printing plates, relief printing plates, and intaglio printing plates.

If the printing plate is applied to a lithographic printing plate, the image thickness is preferably about 0.5 to 1 μm.

If it is applied to a relief printing plate, the image thickness is preferably about 0.3 to 1 μm.

If it is applied to an intaglio printing plate, the image thickness is preferably about 1 to 10 μm. Since intaglio printing requires relatively large image thickness, the known methods cannot manufacture a high-resolution intaglio printing plate. The method of embodiments of the invention can provide a high-resolution printing plate, even though an intaglio printing plate is manufactured.

While the invention has been described with reference to an exemplary embodiment, it is to be understood that the invention is not limited to the disclosed embodiment. For example, the printing plate manufacturing method is not limited to the above-described method, and one or more additional steps may be performed.

Whole in the above embodiment, the printing plate is manufactured using an apparatus shown in FIG. 1 which forms a coating of a printing plate-forming photocurable liquid on a printing original plate by roll coating, the formation of the coating is not limited to this method. The coating may be formed on the printing original plate by any known method, such as gravure coating, bar coating, spray coating, spin coating, knife coating, roll coating, die coating, or dipping.

The apparatus used in the printing plate manufacturing method of embodiments of the invention is not limited to the above-described printing plate manufacturing apparatus, and may further include another member.

The preparation of the printing plate-forming photocurable liquid is also not limited to the above-described procedure.

### EXAMPLES

### (1) Manufacture of Printing Plate

### Example 1

A printing plate-forming photocurable liquid was prepared by mixing 4.5 parts by weight of diphenyliodonium hexafluorophosphate (cationic photopolymerization initiator) and 150 parts by weight of epoxidized linseed oil (epoxy-modified fatty acid ester). The epoxidized linseed oil was prepared by oxidizing (epoxy-modifying) linseed oil with peracetic acid.

A polypropylene film was prepared as the printing original plate.

Subsequently, the printing plate-forming photocurable liquid was uniformly applied onto the surface of the printing original plate to form an uncured coating X, using an apparatus as shown in FIG. 1.

The uncured coating X was selectively irradiated with UV light emitted from the UV irradiation unit of the apparatus as shown in FIG. 1 to cure part of the coating, thus forming an uncured portion and a cured portion in the coating (UV irradiation energy: 70 mJ/cm²; process speed: 331 mm/s).

Subsequently, the uncured portion of the coating was removed by washing with a cleaning solution prepared by dispersing an anionic surfactant (alkylbenzenesulfonate “Ligon LH-200” (product name) produced by Lion Corporation) in water. Thus, an intaglio printing plate was produced. The depth of the recess was 3.4 μm.

### Examples 2 to 10

Printing plates were produced in the same manner as in Example 1 except that the printing plate-forming photocurable liquid had the composition shown in the table.

The table shows the compositions of the printing plate-forming photocurable liquids used in examples. In the table, a represents diphenyliodonium hexafluorophosphate; b represents triphenylsulfonium hexafluorophosphate; c represents 2-hydroxy-1-{4-[4-(2-hydroxy-2-methyl-propionyl)-benzyl]phenyl}-2-methyl-propane-1-one (product name “IRGACURE 127”, produced by CIBA Specialty Chemicals); d represents an oxime ester-containing photopolymerization initiator ethanone, 1-[9-ethyl-6-(2-methylbenzoyl)-9H-carbazole-3-yl], 1-(0-acetyloxime) (product name “IRGACURE OXE02”, produced by CIBA Specialty Chemicals); A represents epoxidized linseed oil; B represents epoxidized soybean oil prepared by oxidizing soybean oil with peracetic acid; C represents an epoxidized rapeseed oil prepared by oxidizing rapeseed oil with peracetic acid; D represents another epoxidized rapeseed oil having a different iodine number from the epoxidized rapeseed oil represented by C, prepared in the same manner as C; F represents epoxidized soybean oil acrylate prepared by reacting epoxidized soybean oil with acrylic acid; G represents epoxidized linseed oil acrylate prepared by reacting an epoxidized linseed oil (produce by Nisshin OilliO) with acrylic acid; and H represents epoxidized rapeseed oil acrylate prepared by reacting epoxidized rapeseed oil (produced by Nisshin OilliO) with acrylic acid.

TABLE

| | Printing plate-forming photocurable liquid | | | | | | | | | | | | | | |
|---|---|---|---|---|---|---|---|---|---|---|---|---|---|---|---|
| | Cationic | | Radical | | | | | | | | | | | | |
| | photo- | | photo- | | | | | | | | | | | | |
| | polymerization | | polymerization | | | | | | | | | | | | |
| | initiator | | initiator | | | | | | | | | | | | |
| | | Content | | Content | | | | | | | | | | | |
| | | (parts by | | (parts by | | | | | | | | | | | |
| | | weight)/ | | weight)/ | | | | | | | | | | | |
| | | 100 | | 100 | Epoxy-modified fatty acid ester | | | | | | Acrylic-modified fatty acid ester | | | | |
| | | parts by | | parts by | | | | | Content | | | | | Content | |
| | | weight of | | weight of | | | | | in | | | | | in | |
| | | epoxy- | | acrylic- | | Raw material | | | photo- | | | | | photo- | |
| | | modified | | modified | | | Iodine | Iodine | curable | | | | | curable | |
| | | fatty | | fatty | | | number | number | liquid | | | Raw | Iodine | liquid | Dura- |
| | Type | acid ester | Type | acid ester | Type | Type | (I₁) | (I₂) | (wt %) | I₁/I₂ | Type | material | number | (wt %) | bility |
| Example 1 | a | 3 | — | — | A | Linseed | 190 | 6 | 100 | 0.032 | — | | — | — | A |
| | | | | | | oil | | | | | | | | | |
| Example 2 | b | 5 | — | — | B | Soybean | 120 | 2 | 100 | 0.016 | — | | — | — | A |
| | | | | | | oil | | | | | | | | | |
| Example 3 | a | 3 | — | — | C | Rapeseed | 100 | 15 | 100 | 0.15 | — | | — | — | A |
| | | | | | | oil | | | | | | | | | |
| Example 4 | a | 3 | — | — | D | Rapeseed | 100 | 18 | 100 | 0.18 | — | | — | — | A |
| | | | | | | oil | | | | | | | | | |
| Example 5 | a | 0.8 | — | — | A | Linseed | 190 | 6 | 100 | 0.032 | — | | — | — | A |
| | | | | | | oil | | | | | | | | | |
| Example 6 | — | — | c | 3 | — | — | — | — | — | — | F | Soybean | 5 | 100 | A |
| | | | | | | | | | | | | oil | | | |
| Example 7 | — | — | d | 5 | — | — | — | — | — | — | G | Linseed | 8 | 100 | A |
| | | | | | | | | | | | | oil | | | |
| Example 8 | — | — | c | 3 | — | — | — | — | — | — | H | Rapeseed | 3 | 100 | A |
| | | | | | | | | | | | | oil | | | |
| Example 9 | — | — | c | 0.8 | — | — | — | — | — | — | F | Soybean | 5 | 100 | A |
| | | | | | | | | | | | | oil | | | |
| Example | a | 3 | c | 3 | A | Linseed | 190 | 6 | 50 | 0.032 | F | Soybean | 5 | 50 | A |
| 10 | | | | | | oil | | | | | | oil | | | |

### [2] Durability (Adhesion)

Scotch mending tape 810-1-18 (width: 10 mm) was stuck across the region from the protruding portion (cured coating) to the recessed portion (from which the uncured portion had been removed) on the resulting intaglio printing plate of each example. The tape was removed toward the protruding portion from the recessed portion at an angle of 170° with respect to the surface of the printing plate at a speed of 5 cm/s. Then, the interface between the protruding portion and the recessed portion was observed through a microscope to check whether or not the coating was separated from the printing original plate.

(A): No separation was observed.

(B): A slight separation was observed, but was insignificant in practice.

(C): Significant separation was observed.

The results are shown in the table. As is clear from the table, the printing plates produced by the method according to an embodiment of the invention exhibited superior durability. Also, printing plates were easily and simply produced by the method according to the embodiment of the invention. Furthermore, the method according to the embodiment of the invention was environmentally friendly.

What is claimed is:

1. A method for manufacturing a printing plate, the method comprising:
applying a printing plate-forming photocurable liquid containing an epoxy-modified fatty acid ester and/or an acrylic-modified fatty acid ester and a photopolymerization initiator onto a printing original plate to form an uncured coating;
selectively irradiating the uncured coating with UV light to cure part of the coating, thus forming an uncured portion and a cured portion in the coating; and
removing the uncured portion of the coating.

2. The method according to claim 1, wherein the UV light have an irradiation energy of 25 to 500 mJ/cm².

3. A printing plate-forming photocurable liquid comprising:
an epoxy-modified fatty acid ester and/or an acrylic-modified fatty acid ester; and
a photopolymerization initiator.

4. The printing plate-forming photocurable liquid according to claim 3, wherein the printing plate-forming photocurable liquid contains the epoxy-modified fatty acid ester, and the photopolymerization initiator is a cationic photopolymerization initiator.

5. The printing plate-forming photocurable liquid according to claim 3, wherein the printing plate-forming photocurable liquid contains the acrylic-modified fatty acid ester, and the photopolymerization initiator is a radical photopolymerization initiator.

6. The printing plate-forming photocurable liquid according to claim 3, wherein the epoxy-modified fatty acid ester is an epoxidized vegetable oil prepared by epoxy-modifying a vegetable oil.

7. The printing plate-forming photocurable liquid according to claim 3, wherein the acrylic-modified fatty acid ester is an epoxidized vegetable oil acrylate prepared by acrylic-modifying an epoxidized vegetable oil prepared by epoxy-modifying a vegetable oil.

8. The printing plate-forming photocurable liquid according to claim 4, wherein the cationic photopolymerization initiator is an aromatic sulfonium salt or an aromatic iodonium salt.

9. The printing plate-forming photocurable liquid according to claim 4, wherein the cationic photopolymerization initiator is contained in a proportion of 0.5 to 8 parts by weight relative to 100 parts by weight of the epoxy-modified fatty acid ester.

10. The printing plate-forming photocurable liquid according to claim 5, wherein the radical photopolymerization initiator is an α-hydroxy ketone compound or an oxime ester compound.

11. The printing plate-forming photocurable liquid according to claim 5, wherein the radical photopolymerization initiator is contained in a proportion of 0.5 to 8 parts by weight relative to 100 parts by weight of the acrylic-modified fatty acid ester.
